(19) United States
(12) Patent Application Publication
(10) Pub. No.: US 2014/0283600 A1
(43) Pub. Date: Sep. 25, 2014

(54) GYRO SENSOR DRIVER AND PULSE TRANSLATION DEVICE USED THEREFOR

(71) Applicant: SAMSUNG ELECTRO-MECHANICS CO., LTD., Suwon (KR)

(72) Inventors: Sung Tae Kim, Suwon (KR); Young Kil Choi, Suwon (KR); Jun Kyung Na, Suwon (KR); Seung Chul Pyo, Suwon (KR); Chang Hyun Kim, Suwon (KR)

(21) Appl. No.: 13/901,799

(22) Filed: May 24, 2013

(30) Foreign Application Priority Data
May 25, 2012 (KR) 10-2012-0056268

(51) Int. Cl. G01C 19/56; H03K 3/012

(52) U.S. Cl. CPC G01C 19/56; H03K 3/012
USPC 73/504.12; 327/299

(57) ABSTRACT

Disclosed herein are a gyro sensor driver and a pulse translation device used thereof. The gyro sensor driver, includes: a phase shifter that delays a signal output from an output terminal of a vibrating sensor to output a phase-shifted signal; a comparator that inverts a signal output from the phase shifter to output a clock signal; a reference voltage generator that generates and outputs reference voltage; and a pulse translator that receives the reference voltage output from the reference voltage generator and the clock signal output from the comparator to generate and output a signal of a predetermined pulse, thereby generating a desired driving signal with low current.

### CROSS REFERENCE TO RELATED APPLICATION

This application claims the benefit of Korean Patent Application No. 10-2012-0056268, filed on May 25, 2012, entitled “Gyro Sensor Driver and Pulse Translation Device Used Therefor”, which is hereby incorporated by reference in its entirety into this application.

### BACKGROUND OF THE INVENTION

1. Technical Field

The present invention relates to a gyro sensor driver and a pulse translation device used therefor.

2. Description of the Related Art

A gyro sensor, which is a sensor detecting angular velocity, has been mainly used for a posture control of an aircraft, a rocket, a robot, and the like, handshaking correction of a camera, binoculars, and the like, vehicle sliding, a lateral turning prevention system, navigation, and the like. Recently, the gyro sensor is also installed in a smart phone and thus, is applied to various applications.

There are various types of gyro sensors. For example, rotatable, vibrating, hydraulic, optical gyro sensors, and the like, have been used. Currently, the vibrating gyro sensor has been mainly used for mobile products.

Further, the vibrating sensor has mainly adopted a capacitive type and sometimes a piezoelectric type.

In the vibrating sensor, a buffer unit providing a driving signal needs to supply large current when a capacitor of the vibrating sensor is large.

Generally, in the vibrating sensor, a capacitor value is generally about 10 pF. However, in case of specific sensors, a capacitor value may exceed several hundreds of pF.

In order to drive the sensors having a large capacitor, a typical buffer type circuit needs current of several hundreds of μA to several mA.

Therefore, the buffer unit in the overall circuit consumes current of several tens of % or more and as a result, consumes a large amount of current.

### PATENT DOCUMENT

Japanese Patent Laid-Open Publication No. 2005-227234

### SUMMARY OF THE INVENTION

The present invention has been made in an effort to provide a gyro sensor driver capable of generating driving voltage with small current and a pulse translation device used therefor.

According to a first preferred embodiment of the present invention, there is provided a gyro sensor driver including: a phase shifter that delays a signal output from an output terminal of a vibrating sensor to output a phase-shifted signal; a comparator that inverts a signal output from the phase shifter to output a clock signal; a reference voltage generator that generates and outputs reference voltage; and a pulse translator that receives the reference voltage output from the reference voltage generator and the clock signal output from the comparator to generate and output a signal of a predetermined pulse.

The pulse translator may include: a high voltage follower that receives and follows high voltage of the reference voltage output from the reference voltage generator; a low voltage follower that receives and follows low voltage of the reference voltage output from the reference voltage generator; a selector that alternately selects a following signal of the high voltage follower or the low voltage follower according to the clock signal output from the comparator; and a buffer that generates and outputs a pulse signal according to selection of the selector.

The high voltage follower may include: a high voltage difference signal generation circuit that outputs a difference signal between high voltage output from the reference voltage generator and a feedback signal; and a high voltage following switch that is connected between a power supply terminal for pulse translation and the selector and turned-on or off according to the difference signal output from the high voltage difference signal generation circuit to maintain the high voltage at an output terminal and may supply the feedback signal to the high voltage difference signal generation circuit via a feedback path.

The high voltage difference signal generation circuit may be configured of an OP AMP of which the non-inverting terminal is connected to a high voltage terminal of a reference voltage output unit and the inverting terminal receives a feedback signal as an input.

The high voltage difference signal generation circuit may be configured of a comparator of which the inverting terminal is connected to a high voltage terminal of a reference voltage output unit and the non-inverting terminal receives a feedback signal as an input.

The low voltage follower may include: a low voltage difference signal generation circuit that outputs the difference signal between the low voltage and the feedback signal; and a low voltage following switch that is connected between the selector and the ground and turned-on or off according to the difference signal output from the low voltage difference signal generation circuit to maintain low voltage at an input terminal and may supply the feedback signal to the low voltage difference signal generation circuit via a feedback path.

The low voltage follower may further include a low voltage buffer circuit that is connected between the feedback path of the low voltage following switch and the low voltage difference signal generation circuit and the ground to prevent peak voltage.

The low voltage buffer circuit may include: a low voltage current source that is connected between the feedback path of the low voltage following switch and the low voltage difference signal generation circuit and the ground to prevent the peak voltage; and a low voltage buffer capacitor that is connected between the feedback path of the low voltage following switch and the low voltage difference signal generation circuit and the ground to prevent the peak voltage.

The low voltage difference signal generation circuit is configured of an OP AMP of which the non-inverting terminal is connected to a low voltage terminal of a reference voltage generator and an inverting terminal receives a feedback signal as an input.

The low voltage difference signal generation circuit may be configured of a comparator of which the inverting terminal is connected to a low voltage terminal of a reference voltage output unit and the non-inverting terminal receives a feedback signal as an input.

The selector may include: a high voltage select switch that selects a high voltage signal maintained at the high voltage follower and outputs the selected high voltage signal to the buffer when a clock signal CLKB clock complementary to a clock signal CLK output from the comparator is high; and a high voltage select switch that selects a low voltage signal maintained at the low voltage follower and outputs the selected low voltage signal to the buffer when the clock signal CLK output from the comparator is high.

The gyro sensor driver may further include: a buffer unit that is connected between the feedback path of the high voltage follower and the feedback path of the low voltage follower to buffer input or output current so as to prevent peak voltage from being generated.

According to a second preferred embodiment of the present invention, there is provided a pulse translation device used for a gyro sensor driver, including: a high voltage follower that receives and follows high voltage of reference voltage; a low voltage follower that receives and follows low voltage of reference voltage; a selector that alternately selects a following signal of the high voltage follower or the low voltage follower according to a clock signal; and a buffer that generates and outputs a pulse signal according a selection of the selector.

The high voltage follower may include: a high voltage difference signal generation circuit that outputs a difference signal between high voltage and a feedback signal; and a high voltage following switch that is connected between a power supply terminal for pulse translation and the selector and turned-on or off according to the difference signal output from the high voltage difference signal generation circuit to maintain the high voltage at an output terminal and may supply the feedback signal to the high voltage difference signal generation circuit via a feedback path.

The high voltage difference signal generation circuit may be configured of an OP AMP of which the non-inverting terminal is connected to a high voltage terminal and the inverting terminal receives a feedback signal as an input.

The high voltage difference signal generation circuit may be configured of a comparator of which an inverting terminal is connected to a high voltage terminal and the non-inverting terminal receives a feedback signal as an input.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a configuration diagram of a gyro sensor driver according to a preferred embodiment of the present invention.

FIG. 2 is a detailed configuration diagram of a reference voltage generator of FIG. 1.

FIG. 3 is a detailed configuration diagram of a pulse translator (or pulse translation device) of FIG. 1 according to a first preferred embodiment of the present invention.

FIGS. 4A and 4G are waveform diagrams relating to the pulse translator (or pulse translation device) of FIG. 3.

FIG. 5 is a detailed configuration diagram of the pulse translator (or pulse translation device) of FIG. 1 according to a second preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

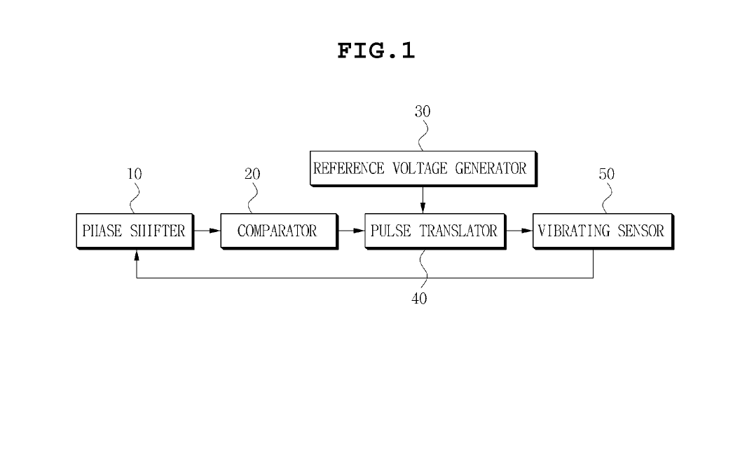

FIG. 1 is a configuration diagram of a driver for a gyro sensor according to a first preferred embodiment of the present invention.

Referring to FIG. 1, the driver for the gyro sensor according to the first preferred embodiment of the present invention includes a phase shifter 10, a comparator 20, a reference voltage generator 30, and a pulse translator 40.

The phase shifter 10 delays a signal output from an output terminal of a vibrating sensor 50 and outputs a signal phase-shifted by 90°.

Further, the comparator 20 shifts a signal output from the phase shifter 10 by 180° and outputs an inverted signal.

The reference voltage generator 30 generates and outputs reference voltage having a range of a predetermined width.

In addition, the pulse translator 40 receives a signal output from the reference voltage generator 30 and receives a clock signal output from the comparator 20 to generate and output a signal of a predetermined pulse.

According to the preferred embodiments of the present invention configured as described above, an output terminal can be designed to consume small current. It is possible to design the driver using current 10% smaller than buffer type driving current according to the prior art.

Further, according to the preferred embodiment of the present invention, it is possible to generate a waveform approximating a squared wave by forming a signal having very short rising time and falling time in the pulse signal.

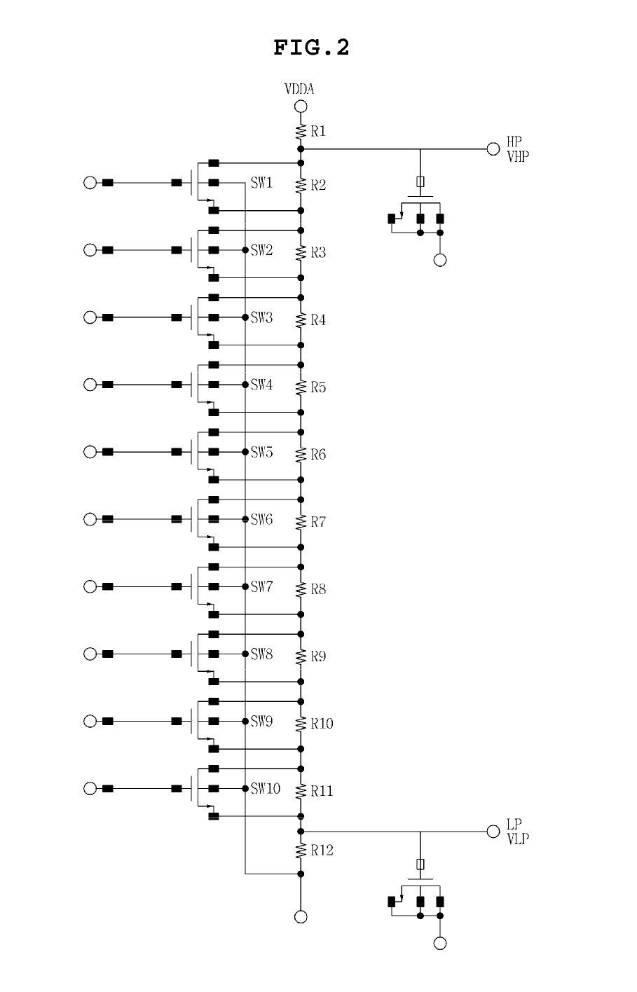

FIG. 2 is a detailed configuration diagram of a reference voltage generator of FIG. 1.

Referring to FIG. 2, the reference voltage generator of FIG. 1 includes a plurality of resistors R1 to R12 that are connected in series and a plurality of switches SW1 to SW10 that supply a bypass path to each resistor.

Terminals of the resistors R1 to R12 are connected with a power supply terminal that supplies reference voltage VDDA to supply reference voltage.

Further, other terminals of the resistors R1 to R12 are connected with a ground to provide an output path for the current.

A high voltage terminal (HP) in the serial connection of the resistors R1 to R12 is not directly connected to the power supply terminal, but connected to the power supply terminal via the resistor R1.

Therefore, high voltage VHP output from the high voltage terminal is maximal, but is smaller than power supply voltage.

Next, a low voltage terminal (LP) is connected to a ground via the resistor R12.

When the low voltage terminal LP is connected to the group via the resistor R12, low voltage VLP output from the low voltage terminal LP is minimal, but is higher than ground voltage.

Meanwhile, the switches SW1 to SW10 each are connected to both ends of the resistors R2 to R11 and are turned-on to provide a bypass path across the corresponding resistor and supply voltage approximating 0 across the corresponding resistor, thereby controlling a magnitude of the high voltage VHP output from the high voltage terminal HP.

Therefore, a magnitude in reference voltage VR supplied from the high voltage terminal and the low voltage terminal is determined according to the number of turned-on switches SW1 to SW10.

In the above configuration, the magnitude in the reference voltage supplied from the high voltage output terminal and the low voltage terminal is defined according to the following Equations 1 and 2 when the voltage supplied from the resistors R2 to R11 is RT.

VHP=VDDA*(RT+R12)/(R1+RT+R12) [Equation 1]

VLP=VDDA*R12/(R1+RT+R12) [Equation 2]

It is preferable that the resistance of the resistors R2 to R11 is larger than that of the R1 or R12 in the reference voltage generator, approximately two times larger. Further, the resistors R1 or R12 may be omitted according to the applied example.

As such, the reference voltage having a predetermined size provided from the reference voltage generator is supplied to the pulse translator and the pulse translator generates and outputs the pulse signal input from the comparator by referring to the reference voltage.

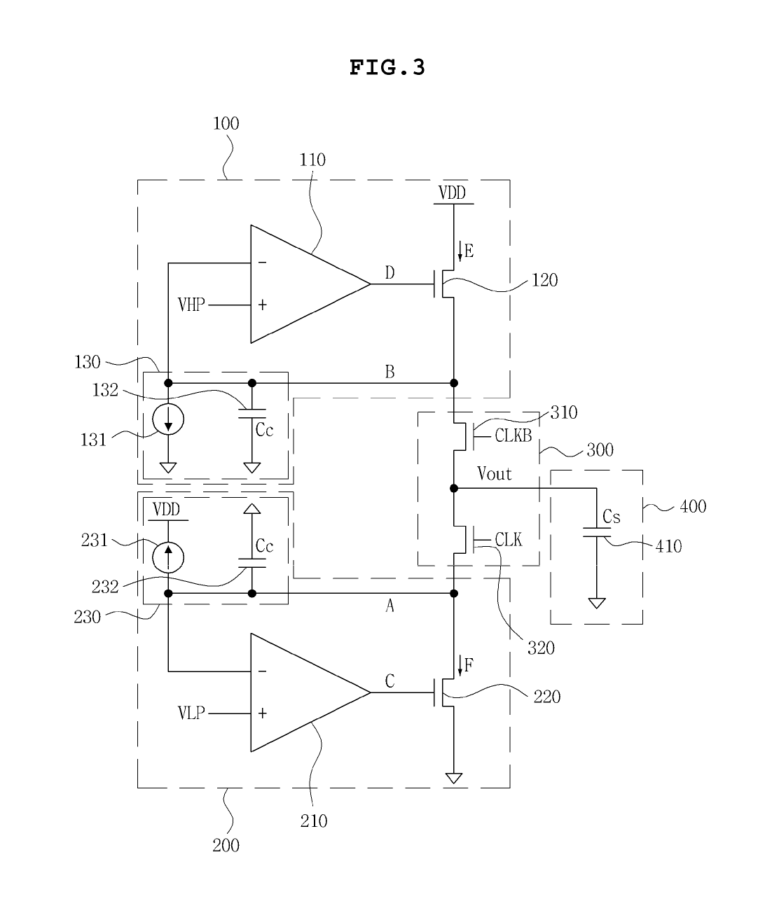

FIG. 3 is a configuration diagram of the pulse translator (or pulse translation device) according to the first preferred embodiment of the present invention.

Referring to FIG. 3, the pulse translator according to the first preferred embodiment of the present invention of FIG. 1 is configured to include a high voltage follower 100, a low voltage follower 200, a selector 300, and a buffer 400.

In this configuration, the high voltage follower 100 includes a high voltage difference signal generation circuit 110 that outputs a difference signal between high voltage output from the reference voltage generator and a feedback signal, a high voltage following switch 120 that is connected between a power supply terminal for pulse translation and a selector and turned-on or off according to the difference signal output from the high voltage difference signal generation circuit 110 to maintain the high voltage at an output terminal and supplies the feedback signal to the high voltage difference signal generation circuit 110 via a feedback path, and a high voltage buffer circuit 130 that is connected between the feedback path of the high voltage following switch 120 and the high voltage difference signal generation circuit 110 and the ground to prevent peak voltage, wherein the high voltage buffer circuit 130 includes a high voltage current source 131 and a high voltage buffer capacitor 132.

The high voltage difference signal generation circuit 110 is configured of an OP AMP of which the non-inverting terminal is connected to the high voltage terminal of the reference voltage output unit and the inverting terminal receives the feedback signal as an input.

The high voltage difference signal generation circuit 110 compares the high voltage signal output from the high voltage terminal of the reference voltage generator with the feedback signal to output the difference signal as a switching control signal. In this case, the high voltage difference signal generation circuit 110 outputs a turned-on switching control signal when the feedback signal is high and outputs turned-off switching control signal when the high voltage signal is high.

In this case, the magnitude of the switching control signal output from the high voltage difference signal generation circuit 110 is in proportion to the difference between the high voltage signal and the feedback signal.

Next, the high voltage following switch 120 is configured of, for example, PMOSFET of which the gate terminal is connected to the output terminal of the high voltage difference signal generator 110, the source terminal is connected to a power supply terminal VDD for pulse translation, and the drain terminal is connected to the inverting terminal of the high voltage difference signal generation circuit 110 via the feedback path.

In addition, a drain terminal of the high voltage following switch 120 is connected to the selector 300.

The high voltage following switch 120 is turned-on when the turned-on switching control signal is input from the output terminal of the high voltage difference signal generation circuit 110 to pass through current input from the power supply terminal for pulse translation.

On the other hand, the high voltage following switch 120 is turned-off when the turned-off switching control signal is input from the output terminal of the high voltage difference signal generation circuit 110 to cut-off current input from the power supply terminal for pulse translation.

Further, the high voltage current source 131 of the high voltage buffer 130 absorbs current suddenly input when the high voltage following switch 120 is turned-on to prevent the peak voltage for being suddenly generated at point B.

Further, the high voltage buffer capacitor 132 of the high voltage buffer 130 absorbs current suddenly input when the high voltage following switch 120 is turned-on to prevent the peak voltage for being suddenly generated at point B.

Meanwhile, the low voltage follower 200 includes a low voltage difference signal generation circuit 210 that outputs the difference signal between the low voltage output from the reference voltage generator and the feedback signal, a low voltage following switch 220 that is connected between the selector 300 and the ground and turned-on or off according to the difference signal output from the low voltage difference signal generation circuit 210 to maintain the low voltage at an input terminal and supplies the feedback signal to the low voltage difference signal generation circuit 110 via the feedback path, and a low voltage buffer circuit 230 that is connected between the feedback path of the low voltage following switch 220 and the low voltage difference signal generation circuit 210 and the ground to prevent peak voltage, wherein the low voltage buffer circuit 230 includes a low voltage current source 231 and a low voltage buffer capacitor 232.

The low voltage difference signal generation circuit 210 is configured of the OP AMP of which the non-inverting terminal is connected to the low voltage terminal of the reference voltage generator and the inverting terminal receives the feedback signal as an input.

The low voltage difference signal generation circuit 210 compares the low voltage signal output from the low voltage terminal of the reference voltage generator with the feedback signal and outputs the difference signal as a switching control signal. In this case, the low voltage difference signal generation circuit 210 outputs a turned-on switching control signal when the feedback signal is high and outputs turned-off switching control signal when the low voltage signal is high.

In this case, the magnitude of the switching control signal output from the low voltage difference signal generation circuit 210 is in proportion to the difference between the low voltage signal and the feedback signal.

Next, the low voltage following switch 220 is configured of for example, NMOSFET of which the gate terminal is connected to the output terminal of the low voltage difference signal generation circuit 210, the drain terminal is connected to the inverting terminal of the low voltage difference signal generation circuit 210 via the feedback path, and the source terminal is connected to the ground.

In addition, the drain terminal of the low voltage following switch 220 is connected to the selector 300.

The low voltage following switch 220 is turned-on when the turned-on switching control signal is input from the output terminal of the low voltage difference signal generation circuit 210 to pass through current input from the selector 300.

On the other hand, the low voltage following switch 220 is turned-off when the turned-off switching control signal is input from the output terminal of the low voltage difference signal generation circuit 210 to cut-off current input from the selector 300.

Further, the low voltage current source 231 of the low voltage buffer circuit 230 absorbs current suddenly input when the low voltage following switch 220 is turned-on to prevent the peak voltage for being suddenly generated at point A.

Further, the low voltage buffer capacitor 232 of the low voltage buffer circuit 230 also absorbs current suddenly input when the low voltage following switch 220 is turned-on to prevent the peak voltage from being suddenly generated at point A.

Next, the selector 300 includes a high voltage select switch 310 and a low voltage select switch 320.

The high voltage select switch 310 selects and outputs the high voltage signal maintained at the high voltage follower 100 when a clock signal CLKB clock complementary to a clock signal CLK output from the comparator 20 is high.

Further, the low voltage select switch 320 selects and outputs the low voltage signal maintained at the low voltage follower 200 when the CLK clock output from the comparator 20 is high. Here, the CLKB clock signal and the CLK clock have a complementary signal to each other.

In the configuration, the high voltage select switch 310 is configured of, for example, PMOSFET and the external CLKB clock signal is received as an input through the gate terminal thereof; the source terminal thereof is connected to the drain terminal of the high voltage following switch 120, and the drain terminal thereof is connected to the drain terminal of the low voltage select switch 320.

In addition, the drain terminal of the high voltage select switch 310 is connected to a buffer 400 and supplies the input current to the buffer 400 to charge the buffer 400.

The high voltage select switch 310 is turned-on when the CLKB signal in a high state is input through the gate terminal thereof to make the voltage at the point B instantly equal to the voltage of the buffer 400 while supplying the input current to the buffer 400 to charge the buffer 400.

Through this operation, the buffer 400 follows the high voltage supplied from the reference voltage generator that is maintained at the high voltage follower 100 when the high voltage select switch 310 is turned-on to generate and output the high voltage pulse.

Next, the low voltage select switch 320 is configured of, for example, NMOSFET. Here, the CLK clock signal is received through the gate terminal thereof; the drain terminal thereof is connected to the drain terminal of the high voltage select switch 310 and the input terminal of the buffer 400, and the source terminal thereof is connected to the drain terminal of the low voltage following switch 220.

The low voltage select switch 320 is turned-on when the CLK signal in a high state is input through the gate terminal thereof to make the voltage at the point A instantly equal to the voltage of the buffer 400 to discharge current from the buffer 400.

By the operation, the buffer 400 follows the low voltage supplied from the reference voltage generator that is maintained at the low voltage follower 200 when the low voltage select switch 320 is turned-on to generate and output the low voltage pulse.

Meanwhile, the buffer 400 is configured of a buffer capacitor Cs 410 and repeats charging and discharging according to a signal output from the output terminal thereof to generate and output the pulse signal.

An operation of the pulse translator having the above structure will be described below.

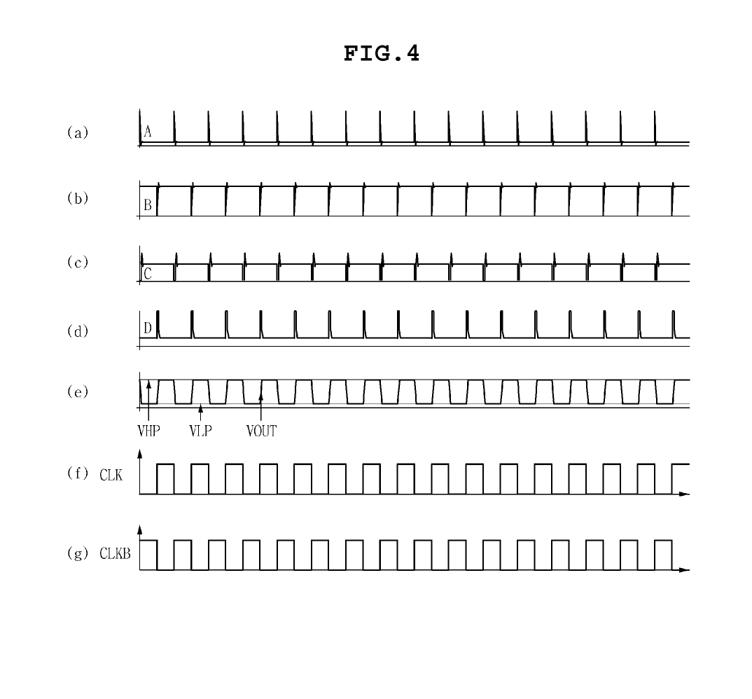

First, when the high voltage select switch 310 and the low voltage select switch 320 of the selector 300 are turned-off, the points A and B are each maintained at VLP and VHP voltage by the feedback path (see a waveform of FIGS. 4A and 4B).

That is, the high voltage difference signal generation circuit 110 and the low voltage difference signal generation circuit 210 have characteristics to make the inverting terminal and the non-inverting terminal maintain the same voltage and when both of the high voltage select switch 310 and the low voltage select switch 320 are turned-off; the points A and B are each maintained at VLP and VHP voltage by the feedback path.

Meanwhile, it is assumed that the buffer capacitor Cs 410 of the buffer 400 is charged at the VHP voltage in an initial state. In this situation, when the low voltage select switch 320 is turned-on, the voltage at the point A is suddenly changed to the voltage VHP of the buffer capacitor Cs.

That is, the voltage at the point A is VLP before the low voltage select switch 320 is turned-on and then, when the low voltage select switch 320 is turned-on, the voltage at the point A is suddenly changed to the voltage VHP of the buffer capacitor Cs 410.

When the voltage at the point A is suddenly changed, the voltage difference is generated across the low voltage difference signal generation circuit 210 and thus, the low voltage difference signal generation circuit 210 outputs the turned-on switching control signal to the gate terminal of the low voltage following switch 220.

As described above, when the turned-on switching control signal is input to the gate terminal, the low voltage following switch 220 is turned-on to reduce the voltage thereacross to the VLP voltage. Therefore, the voltage at the point A of the input terminal of the inverting terminal of the low voltage difference signal generation circuit 210 is reduced to the VLP voltage and the voltage at the point A maintains the VLP voltage by the operation.

In this state, when the current of the buffer capacitor Cs 410 of the buffer 400 flows in the ground side to further reduce the voltage, since the voltage at the point A is lower than the VLP, the low voltage difference signal generation circuit 210 outputs the turned-off switching control signal to increase voltage at point C again (see a waveform of FIG. 4C).

Therefore, the low voltage following switch 220 at point F is turned-off to reduce current, such that the voltage to be reduced is maintained so as not to reduce to the VLP or less.

When the low voltage select switch 320 receiving the CLK as an input is turned-on by the operation, the buffer capacitor Cs 410 is changed to the VLP voltage.

Similarly, when the low voltage select switch 320 receiving the CLK as an input is turned-off and the high voltage select switch 310 receiving as an input the CLKB (see a waveform diagram of FIG. 3E) that is the clock signal complementary to the CLK (see a waveform diagram of FIG. 4F) is turned-on, the voltage of the buffer capacitor Cs 410 is changed to the VHP.

In this case, it is assumed that the buffer capacitor Cs 410 of the buffer 400 is charged at the VLP voltage. In this situation, when the high voltage select switch 310 is turned-on, the voltage at the point B is suddenly changed to the voltage VLP of the buffer capacitor Cs 410 (see a waveform of FIG. 4B).

That is, the voltage at the point B is VHP before the high voltage select switch 310 is turned-on and then, when the high voltage select switch 310 is turned-on, the voltage at the point B is suddenly changed to the voltage VLP of the buffer capacitor Cs 410.

As described above, when the voltage at the point B is suddenly changed, the voltage difference is generated across the high voltage difference signal generation circuit 110 and thus, the high voltage difference signal generation circuit 110 outputs the turned-on switching control signal to the gate terminal of the high voltage following switch 120.

As described above, when the turned-on switching control signal is input to the gate terminal, the high voltage following switch 120 is turned-on to increase the voltage thereacross to the VHP voltage. Therefore, the voltage at the point B of the input terminal of the inverting terminal of the high voltage difference signal generation circuit 110 is increased to the VHP voltage and the voltage at the point B maintains the VHP voltage by the operation.

In this state, when the current flows in the buffer capacitor Cs 410 of the buffer 400 side to further increase the voltage, since the voltage at the point B is higher than the VHP, the high voltage difference signal generation circuit 110 outputs the turned-off switching control signal to reduce voltage at point D again (see a waveform of FIG. 4D).

Therefore, the high voltage following switch 120 at the point D is turned-off to reduce current, such that the voltage to be increased is maintained so as not to increase to the VHP or more.

When the high voltage select switch 310 receiving the CLKB as an input is turned-on by the operation, the buffer capacitor Cs 410 is changed to the VHP voltage.

As described above, when the buffer capacitor Cs 410 is changed from the VLP voltage to the VHP voltage and to the VLP voltage again, the pulse waveform is output (see a waveform of FIG. 4E).

Meanwhile, overshoot may occur at the point A or the point B and the high voltage buffer circuit 130 and the low voltage buffer circuit 230 absorb the overshoot for each voltage to prevent the occurrence of overshoot.

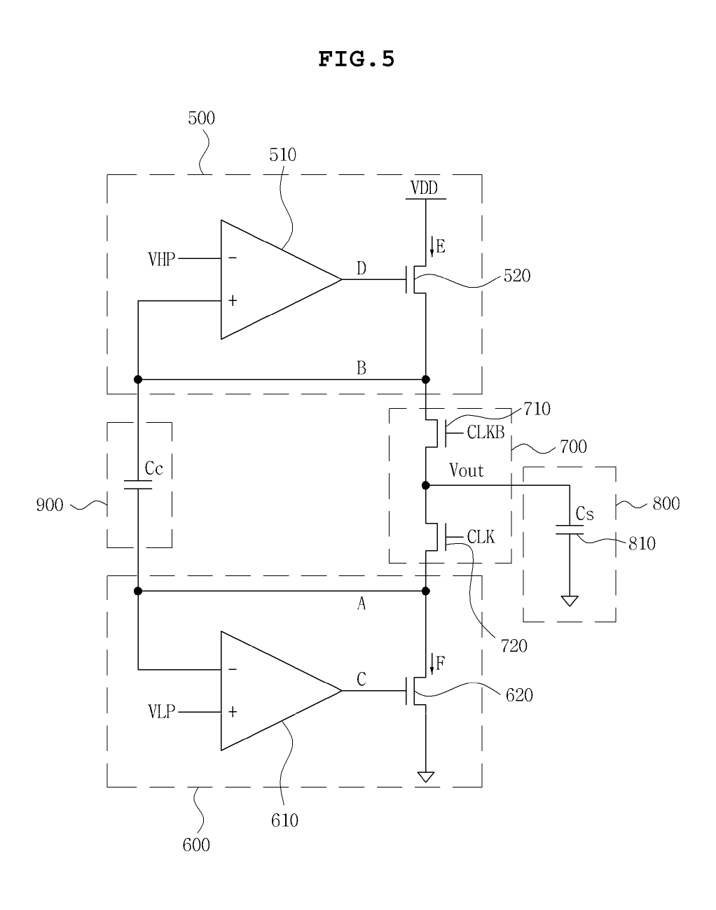

FIG. 5 shows a structure of the pulse translator (or pulse translation device) of FIG. 1 according to a second preferred embodiment of the present invention.

Referring to FIG. 5, the pulse translator according to the first preferred embodiment of the present invention of FIG. 1 is configured to include a high voltage follower 500, a low voltage follower 600, a selector 700, a buffer 800, and a buffer 900.

In this configuration, the high voltage follower 500 includes a high voltage difference signal generation circuit 510 that receives the high voltage output from the reference voltage generator to output the difference signal from the feedback signal as the switching control signal and follow the high voltage so as to maintain the high voltage signal and a high voltage following switch 520.

The high voltage difference signal generation circuit 510 is configured of an OP AMP of which the inverting terminal is connected to the high voltage terminal of the reference voltage generator and the non-inverting terminal receives the feedback signal as an input.

The high voltage difference signal generation circuit 510 compares the high voltage signal output from the high voltage terminal of the reference voltage generator with the feedback signal and outputs the difference signal as a switching control signal. In this case, the high voltage difference signal generation circuit 510 outputs the turned-on switching control signal when the feedback signal is high and outputs a turned-off switching control signal when the high voltage signal is high.

In this case, the magnitude of the switching control signal output from the high voltage difference signal generation circuit 510 is in proportion to the difference between the high voltage signal and the feedback signal.

Next, the high voltage following switch 520 is configured of, for example, PMOSFET of which the gate terminal is connected to an output terminal of the high voltage difference signal generator 510, the source terminal is connected to the power supply terminal VDD for pulse translation, and the drain terminal is connected to a non-inverting terminal of the high voltage difference signal generation circuit 510 via the feedback path.

In addition, the drain terminal of the high voltage following switch 520 is connected to the selector 700.

As described above, the high voltage following switch 520 is turned-on when the turned-on switching control signal is input from the output terminal of the high voltage difference signal generation circuit 510 to pass through current input from the power supply terminal for pulse translation.

On the other hand, the high voltage following switch 520 is turned-off when the turned-off switching control signal is input from the output terminal of the high voltage difference signal generation circuit 510 to cut-off current input from the power supply terminal for pulse translation.

Meanwhile, the low voltage follower 600 includes a low voltage difference signal generation circuit 610 that compares the low voltage output from the reference voltage generator with the feedback signal to output the difference signal and follow the low voltage so as to maintain the low voltage signal and a low voltage following switch 620.

The low voltage difference signal generation circuit 610 is configured of the OP AMP of which the inverting terminal is connected to the low voltage terminal of the reference voltage generator and the non-inverting terminal receives the feedback signal as an input.

As described above, the low voltage difference signal generation circuit 610 compares the low voltage signal output from the low voltage terminal of the reference voltage generator with the feedback signal and generates and outputs the difference signal as a switching control signal. In this case, the low voltage difference signal generation circuit 610 outputs the turned-on switching control signal when the feedback signal is high and outputs the turned-off switching control signal when the low voltage signal is high.

In this case, the magnitude of the switching control signal output from the low voltage difference signal generation circuit 610 is in proportion to the difference between the low voltage signal and the feedback signal.

Next, the low voltage following switch 620 is configured of for example, NMOSFET of which the gate terminal is connected to the output terminal of the low voltage difference signal generation circuit 610, the drain terminal is connected to the non-inverting terminal of the low voltage difference signal generation circuit 610 via the feedback path, and the source terminal is connected to the ground.

In addition, the drain terminal of the low voltage following switch 620 is connected to the selector 700.

As described above, the low voltage following switch 620 is turned-on when the turned-on switching control signal is input from the output terminal of the low voltage difference signal generation circuit 610 to pass through current input from the selector 700.

On the other hand, the low voltage following switch 620 is turned-off when the turned-off switching control signal is input from the output terminal of the low voltage difference signal generation circuit 610 to cut-off the current input from the selector 700.

Next, the selector 700 includes a high voltage select switch 710 and a low voltage select switch 720.

The high voltage select switch 710 selects and outputs the high voltage signal maintained at the high voltage follower 500 when the CLKB clock output from the comparator 20 is high.

Further, the low voltage select switch 720 selects and outputs the low voltage signal maintained at the low voltage follower 600 when the CLK clock output from the comparator 20 is high.

Here, the signals of the CLKB clock signal and the CLK clock are complementary to each other.

In the configuration, the high voltage select switch 710 is configured of for example, PMOSFET and the external CLKB clock signal is received through the gate terminal thereof, the source terminal thereof is connected to the drain terminal of the high voltage following switch 720, and the drain terminal thereof is connected to the drain terminal of the low voltage select switch 720.

In addition, the drain terminal of the high voltage select switch 710 is connected to a buffer 800 and supplies the input current to the buffer 800 to charge the buffer 800.

The high voltage select switch 710 is turned-on when the CLKB signal in a high state is input through the gate terminal thereof to make the voltage at the point B instantly equal to the voltage of the buffer 800 while supplying the input current to the buffer 800 to charge the buffer 800.

By the operation, the buffer 800 follows the high voltage supplied from the reference voltage generator that is maintained at the high voltage follower 500 when the high voltage select switch 710 is turned-on to generate and output the high voltage pulse.

Next, the low voltage select switch 720 is configured of, for example, NMOSFET and the CLK clock signal is received through the gate terminal thereof, the drain terminal thereof is connected to the drain terminal of the high voltage select switch 710 and the input terminal of the buffer 800, and the source terminal thereof is connected to the drain terminal of the low voltage following switch 720.

The low voltage select switch 720 is turned-on when the CLK signal in a high state is input through the gate terminal thereof to make the voltage at the point A instantly equal to the voltage of the buffer 800 to discharge current from the buffer 800.

Through this operation, the buffer 800 follows the low voltage supplied from the reference voltage generator that is maintained at the low voltage follower 600 when the low voltage select switch 720 is turned-on to generate and output the low voltage pulse.

Meanwhile, the buffer 800 is configured of a buffer capacitor Cs 810 and repeats charging and discharging according to a signal output from the output terminal thereof to generate and output the pulse signal.

Further, a buffer 900 is connected between the feedback path of the high voltage follower 500 and the feedback path of the low voltage follower 600 to buffer the suddenly input or output current, thereby preventing the sudden peak voltage from being generated at the point A or the point B. The buffer 900 may be configured of a buffer capacitor 910.

An operation of the pulse translator having the above structure will be described below.

First, when the high voltage select switch 710 and the low voltage select switch 720 of the selector 700 are turned-off, the points A and B are each maintained at VLP and VHP voltage by the feedback path.

Meanwhile, it is assumed that the buffer capacitor Cs 810 of the buffer 800 is charged at the VHP voltage in an initial state. In this situation, when the low voltage select switch 720 is turned-on, the voltage at the point A is suddenly changed to the voltage VHP of the buffer capacitor Cs 810.

As described above, when the voltage at the point A is suddenly changed, the voltage difference is generated across the low voltage difference signal generation circuit 610 and thus, the low voltage difference signal generation circuit 610 outputs the turned-on switching control signal to the gate terminal of the low voltage following switch 620.

As described above, when the turned-on switching control signal is input to the gate terminal thereof, the low voltage following switch 620 is turned-on to reduce the voltage thereacross to the VLP voltage. Therefore, the voltage at the point A of the input terminal of the non-inverting terminal of the low voltage difference signal generation circuit 610 is reduced to the VLP voltage and the voltage at the point A maintains the VLP voltage by the operation.

In this state, when the current of the buffer capacitor Cs 810 of the buffer 800 flows in the ground side to further reduce the voltage, since the voltage at the point A is lower than the VLP, the low voltage difference signal generation circuit 610 outputs the turned-off switching control signal to increase the voltage at the point C again.

Therefore, the low voltage following switch 220 at the point F is turned-off to reduce current, such that the voltage to be reduced is maintained so as not to reduce to the VLP or less.

When the low voltage select switch 720 receiving the CLK as an input is turned-on by the operation, the buffer capacitor Cs 810 is changed to the VLP voltage.

Similarly, when the low voltage select switch 720 receiving the CLK as an input is turned-off and the high voltage select switch 610 receiving as an input the CLKB that is the clock signal complementary to the CLK is turned-on, the voltage of the buffer capacitor Cs 810 is changed to the VHP.

In this case, it may be assumed that the buffer capacitor Cs 810 of the buffer 800 is charged at the VLP voltage. In this situation, when the high voltage select switch 510 is turned-on, the voltage at the point B is suddenly changed to the voltage VLP of the buffer capacitor Cs 810.

As described above, when the voltage at the point B is suddenly changed, the voltage difference is generated across the high voltage difference signal generation circuit 510 and thus, the high voltage difference signal generation circuit 510 outputs the turned-on switching control signal to the gate terminal of the high voltage following switch 520.

As described above, when the turned-on switching control signal is input to the gate terminal, the high voltage following switch 520 is turned-on to increase the voltage thereacross to the VHP voltage. Therefore, the voltage at the point B of the input terminal of the inverting terminal of the high voltage difference signal generation circuit 510 is increased to the VHP voltage and the voltage at the point B maintains the VHP voltage by the operation.

In this state, when the current flows in the buffer capacitor Cs 810 side of the buffer 800 to further increase the voltage, since the voltage at the point B is higher than the VHP, the high voltage difference signal generation circuit 510 outputs the turned-off switching control signal to reduce voltage at point D again.

Therefore, the high voltage following switch 520 at the point D is turned-off to reduce current, such that the voltage to be increased is maintained so as not to increase to the VHP or more.

When the high voltage select switch 710 receiving the CLKB as an input is turned-on by the operation, the buffer capacitor Cs 810 is changed to the VHP voltage.

As described above, when the buffer capacitor Cs 810 is changed from the VLP voltage to the VHP voltage and to the VLP voltage again, the pulse waveform is output.

Meanwhile, overshoot may occur at the point A or the point B and the buffer 900 absorb the overshoot for each voltage to prevent the occurrence of overshoot.

Although two types of pulse translators is described above, an extremely small amount of current always flows in the pulse translator of FIG. 3 according to the first preferred embodiment by the current sources 131 and 231. However, in the case of the pulse translator of FIG. 5 according to the second preferred embodiment of the present invention, minimal current flows when being stabilized after the state transition.

That is, when viewing from the point B, the pulse translator of FIG. 3 always maintains the fixed voltage in the case in which the switches are turned-off and the pulse translator of FIG. 5 proceeds to a direction in which voltage continues to increase due to leakage current over time (does not proceed in a direction in which voltage is reduced).

That is, the present invention does not need a compensation capacitor but instead can use an OP AMP and therefore, may apply the high-speed comparator to the difference signal generation circuits 510 and 610.

In addition, when the comparator is used as the difference signal generator, voltage continues to increase due to a very rapid speed to cut-off current flowing in a switch immediately after the voltage exceeds the VHP.

Unlike this, when the low-speed OP AMP is used, the current of the switch is cut-off later, such that the voltage at the point B may be higher than VHP.

Despite these advantages, the structure of FIG. 5 has a limited speed and thus, slight error is present, no matter how rapidly the speed of the comparator is.

Meanwhile, according to the preferred embodiments of the present invention, the output terminal can be designed to consume small current. That is, according to the preferred embodiments of the present invention, it is possible to obtain the driving signal with about 10% less current than the buffer type gyro sensor driver according to the prior art.

Further, according to the preferred embodiments of the present invention, it is possible to generate a waveform with high precision approximating the squared wave by greatly shortening the rising time and the falling time.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A gyro sensor driver, comprising:
a phase shifter that delays a signal output from an output terminal of a vibrating sensor to output a phase-shifted signal;
a comparator that inverts a signal output from the phase shifter to output a clock signal;
a reference voltage generator that generates and outputs reference voltage; and
a pulse translator that receives the reference voltage output from the reference voltage generator and the clock signal output from the comparator to generate and output a signal at a predetermined pulse.

2. The gyro sensor driver as set forth in claim 1, wherein the reference voltage generator includes:
a plurality of resistors that are connected in series; and
a plurality of switches that provide a bypass path to each resistor.

3. The gyro sensor driver as set forth in claim 2, wherein the reference voltage output from the reference voltage generator is determined according to the number of turned-on switches.

4. The gyro sensor driver as set forth in claim 1, wherein the pulse translator includes:
a high voltage follower that receives and follows high voltage of the reference voltage output from the reference voltage generator;
a low voltage follower that receives and follows low voltage of the reference voltage output from the reference voltage generator;
a selector that alternately selects a following signal of the high voltage follower or the low voltage follower according to the clock signal output from the comparator; and
a buffer that generates and outputs a pulse signal according to selection of the selector.

5. The gyro sensor driver as set forth in claim 4, wherein the high voltage follower includes:
a high voltage difference signal generation circuit that outputs a difference signal between high voltage output from the reference voltage generator and a feedback signal; and
a high voltage following switch that is connected between a power supply terminal for pulse translation and the selector and turned-on or off according to the difference signal output from the high voltage difference signal generation circuit to maintain the high voltage at an output terminal and supplies the feedback signal to the high voltage difference signal generation circuit via a feedback path.

6. The gyro sensor driver as set forth in claim 5, wherein the high voltage follower further includes a high voltage buffer circuit that is connected between the feedback path of the high voltage following switch and the high voltage difference signal generation circuit and the ground to prevent peak voltage.

7. The gyro sensor driver as set forth in claim 6, wherein the high voltage buffer circuit includes:
a high voltage current source that is connected between the feedback path of the high voltage following switch and the high voltage difference signal generation circuit and the ground to prevent the peak voltage; and
a high voltage buffer capacitor that is connected between the feedback path of the high voltage following switch and the high voltage difference signal generation circuit and the ground to prevent the peak voltage.

8. The gyro sensor driver as set forth in claim 4, wherein the high voltage difference signal generation circuit is configured of an OP AMP of which the non-inverting terminal is connected to a high voltage terminal of a reference voltage output unit and the inverting terminal receives a feedback signal as an input.

9. The gyro sensor driver as set forth in claim 4, wherein the high voltage difference signal generation circuit is configured of a comparator of which the inverting terminal is connected to a high voltage terminal of a reference voltage output unit and the non-inverting terminal receives a feedback signal as an input.

10. The gyro sensor driver as set forth in claim 4, wherein the low voltage follower includes:
a low voltage difference signal generation circuit that outputs the difference signal between the low voltage and the feedback signal; and
a low voltage following switch that is connected between the selector and the ground and turned-on or off according to the difference signal output from the low voltage difference signal generation circuit to maintain low voltage at an input terminal and supplies the feedback signal to the low voltage difference signal generation circuit via a feedback path.

11. The gyro sensor driver as set forth in claim 10, wherein the low voltage follower further includes a low voltage buffer circuit that is connected between the feedback path of the low voltage following switch and the low voltage difference signal generation circuit and the ground to prevent peak voltage.

12. The gyro sensor driver as set forth in claim 10, wherein the low voltage buffer circuit includes:
a low voltage current source that is connected between the feedback path of the low voltage following switch and the low voltage difference signal generation circuit and the ground to prevent the peak voltage; and
a low voltage buffer capacitor that is connected between the feedback path of the low voltage following switch and the low voltage difference signal generation circuit and the ground to prevent the peak voltage.

13. The gyro sensor driver as set forth in claim 10, wherein the low voltage difference signal generation circuit is configured of an OP AMP of which the non-inverting terminal is connected to and a low voltage terminal of a reference voltage generator and the inverting terminal receives a feedback signal as an input.

14. The gyro sensor driver as set forth in claim 10, wherein the low voltage difference signal generation circuit is configured of a comparator of which the inverting terminal is connected to a low voltage terminal of a reference voltage output unit and the non-inverting terminal receives a feedback signal as an input.

15. The gyro sensor driver as set forth in claim 4, wherein the selector includes:
a high voltage select switch that selects a high voltage signal maintained at the high voltage follower and outputs the selected high voltage signal to the buffer when a clock signal CLKB clock complementary to a clock signal CLK output from the comparator is high; and
a high voltage select switch that selects a low voltage signal maintained at the low voltage follower and outputs the selected low voltage signal to the buffer when the clock signal CLK output from the comparator is high.

16. The gyro sensor driver as set forth in claim 4, further comprising: a buffer unit that is connected between the feedback path of the high voltage follower and the feedback path of the low voltage follower to buffer input or output current so as to prevent peak voltage from being generated.

17. A pulse translation device used for a gyro sensor driver, comprising:
a high voltage follower that receives and follows high voltage of reference voltage;
a low voltage follower that receives and follows low voltage of reference voltage;
a selector that alternately selects a following signal of the high voltage follower or the low voltage follower according to a clock signal; and
a buffer that generates and outputs a pulse signal according to a selection of the selector.

18. The pulse translation device as set forth in claim 17, wherein the high voltage follower includes:
a high voltage difference signal generation circuit that outputs a difference signal between high voltage and a feedback signal; and
a high voltage following switch that is connected between a power supply terminal for pulse translation and the selector and turned-on or off according to the difference signal output from the high voltage difference signal generation circuit to maintain the high voltage at an output terminal and supplies the feedback signal to the high voltage difference signal generation circuit via a feedback path.

19. The pulse translation device as set forth in claim 17, wherein the high voltage difference signal generation circuit is configured of an OP AMP of which the non-inverting terminal is connected to a high voltage terminal and the inverting terminal receives a feedback signal as an input.

20. The pulse translation device as set forth in claim 17, wherein the high voltage difference signal generation circuit is configured of a comparator of which the inverting terminal is connected to a high voltage terminal and the non-inverting terminal receives a feedback signal as an input.

21. The pulse translation device as set forth in claim 17, wherein the low voltage follower includes:
a low voltage difference signal generation circuit that outputs the difference signal between the low voltage and the feedback signal; and
a low voltage following switch that is connected between the selector and the ground and turned-on or off according to the difference signal output from the low voltage difference signal generation circuit to maintain low voltage at an input terminal and supplies the feedback signal to the low voltage difference signal generation circuit via a feedback path.

22. The pulse translation device as set forth in claim 17, wherein the low voltage difference signal generation circuit is configured of an OP AMP of which the non-inverting terminal is connected to and a low voltage terminal and the inverting terminal receives a feedback signal as an input.

23. The pulse translation device as set forth in claim 17, wherein the low voltage difference signal generation circuit is configured of a comparator of which the inverting terminal is connected to a low voltage terminal and the non-inverting terminal receives a feedback signal as an input.

24. The pulse translation device as set forth in claim 17, wherein the selector includes:
a high voltage select switch that selects a high voltage signal maintained at the high voltage follower and outputs the selected high voltage signal to the buffer when a clock signal CLKB clock complementary to a clock signal CLK is high; and
a low voltage select switch that selects a low voltage signal maintained at the low voltage follower and outputs the selected low voltage signal to the buffer when the clock signal CLK is high.

25. The pulse translation device as set forth in claim 17, further comprising: a buffer unit that is connected between the feedback path of the high voltage follower and the feedback path of the low voltage follower to buffer input or output current so as to prevent peak voltage from being generated.
